(19) United States
(12) Patent Application Publication
(10) Pub. No.: US 2025/0062766 A1
(43) Pub. Date: Feb. 20, 2025

(54) CONTINUOUS SIGNAL LEVEL SHIFTER

(71) Applicant: TEXAS INSTRUMENTS INCORPORATED, Dallas, TX (US)

(72) Inventors: Kyoung Min Lee, Cary, NC (US); Satish Vemuri, Raleigh, NC (US)

(21) Appl. No.: 18/490,961

(22) Filed: Oct. 20, 2023

Related U.S. Application Data
(60) Provisional application No. 63/532,987, filed on Aug. 16, 2023.

(51) Int. Cl. H03K 19/0185; H03K 5/24

(52) U.S. Cl. CPC H03K 19/018528; G01R 19/16566; H03K 5/2481; H03K 19/20

(57) ABSTRACT

A driver includes a current generator having an input and first and second outputs. The current generator generates a first current at the first output while a signal at the input is at a first logic state and generates a second current at the second output while the signal at the input is at a second logic state. A comparator has a first comparator input, a second comparator input, and a first comparator output, and a second comparator output. The first comparator input is coupled to the first output, and the second comparator input is coupled to the second output. A latch has a first latch input, a second latch input, and a latch output. The first latch input is coupled to the first comparator output, and the second latch input is coupled to the second comparator output. A gate control circuit has an input coupled to the latch output.

### CROSS-REFERENCE TO RELATED APPLICATIONS

This application claims priority to U.S. Provisional Application No. 63/532,987, filed Aug. 16, 2023, titled “High Speed/Sensitivity Level Shifter With Continuous Signal Delivery,” and which is hereby incorporated by reference.

### BACKGROUND

For many applications, a pair of transistors are coupled in series between a supply voltage (e.g., 600V) and ground. The transistor coupled to the supply voltage may be referred to as the “high side” (HS) transistor, and the transistor coupled to ground may be referred to as the “low side” (LS) transistor. In an implementation in which the HS transistor is a field effect transistor (FET), the source of the HS transistor may not be coupled to ground. Instead, the HS transistor's source may have a voltage that varies, with respect to ground, from 0V to the supply voltage, e.g., 600V. Turning on the HS transistor includes providing a gate voltage that is at least the threshold voltage of the transistor above its source voltage. Accordingly, a driver applies a voltage to the gate of the HS transistor to turn on the transistor that is at least a threshold voltage above a voltage (the source voltage) that may vary from 0V to the supply voltage. The driver may include a level shift circuit to generate a suitably high gate voltage based on a relatively low voltage control signal (e.g., 5V).

### SUMMARY

A driver includes a current generator having an input and first and second outputs. The current generator generates a first current at the first output while a signal at the input is at a first logic state and generates a second current at the second output while the signal at the input is at a second logic state. A comparator has a first comparator input, a second comparator input, and a first comparator output, and a second comparator output. The first comparator input is coupled to the first output, and the second comparator input is coupled to the second output. A latch has a first latch input, a second latch input, and a latch output. The first latch input is coupled to the first comparator output, and the second latch input is coupled to the second comparator output. A gate control circuit has an input coupled to the latch output.

### BRIEF DESCRIPTION OF THE DRAWINGS

FIG. 1 is a schematic diagram of a system which includes, among other components, a controller and a driver, in an example.

FIG. 2 is a schematic diagram of a high side driver within the driver of FIG. 1 including a comparator, in an example.

FIG. 3 is a schematic diagram of the comparator of FIG. 2, in an example.

FIG. 4 is a timing diagram illustrating the operation of the high side driver of FIG. 2, in an example.

### DETAILED DESCRIPTION

The same reference numbers or other reference designators are used in the drawings to designate the same or similar (either by function and/or structure) features.

One type of level shift circuit is a pulse-based circuit which generates a short duration set current pulse based on a rising edge of an input control signal and generates a short duration reset current pulse based on the falling edge of the input control signal. The level shift circuit includes a comparator that compares the set current pulse to the reset current pulse. The level shift circuit causes the HS transistor to turn on if the set current pulse is larger than the reset current pulse and turns off the HS transistor if the set current pulse is smaller than the reset current pulse. The width of each current pulse is small enough that it is possible for the comparator to “miss” or “skip” a pulse. If the comparator fails to detect the reset current pulse, the HS transistor unfortunately will not be turned off. Further, such pulse-based level shift circuits can be relatively slow to respond to a set or reset current pulse.

The examples described herein pertain to a continuous signal level shift circuit. In one example, the level shift circuit generates a continuous set current while the input control signal is in a first logic state (e.g., logic high). When the input control signal changes logic state to a second logic state (e.g., logic low), the level shift circuit turns off the set current and generates a continuous reset current which flows as long as the input control signal remains in the second logic state. Because the described continuous signal level shift circuit is not a pulse-based circuit, the risk of skipping a pulse is negligible or zero. Further, the described continuous signal level shift circuit includes a current comparator that is faster than comparators that may be used in pulse-based level shift circuits.

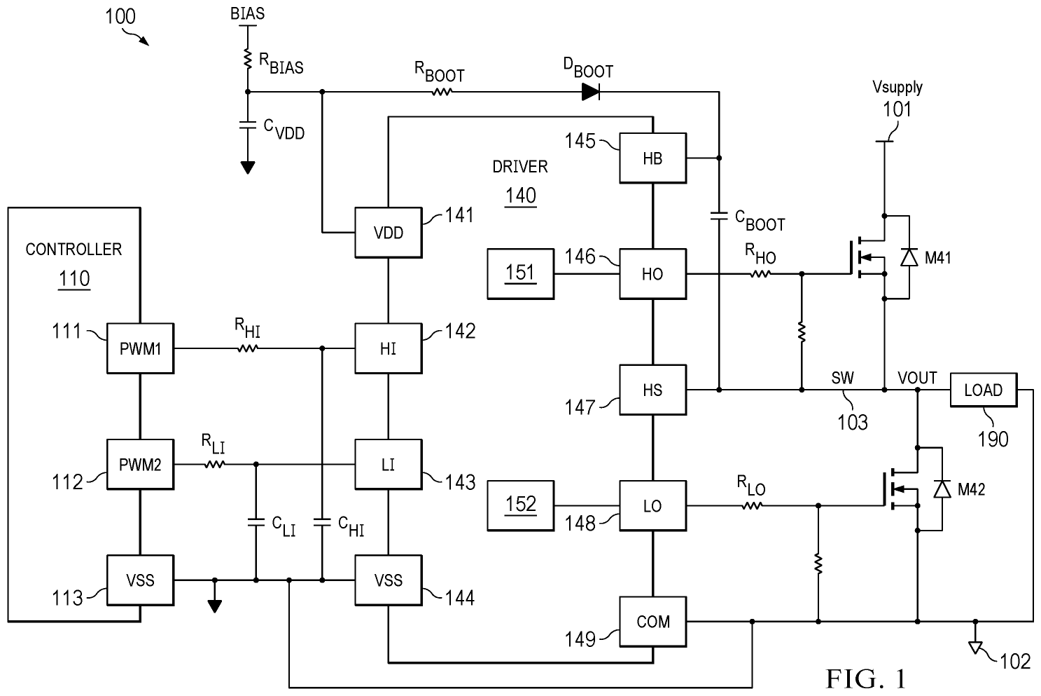

FIG. 1 is a schematic diagram of a system 100 which includes a controller 110, a driver 140, transistors M41 and M42, and a load 190. In one example, load 190 may include any or all of an inductor, a capacitor, and a circuit to receive the output voltage VOUT. System 100 may be a voltage converter such as a buck converter, a boost converter, a motor drive, etc. Transistors are n-channel field effect transistors (NFETs) in this example but can be implemented as other types of transistors in other examples. Transistors M41 and M42 are coupled in series between a voltage supply (Vsupply) terminal 101 and a ground terminal 102. The drain of transistor M42 is coupled to the source of transistor M41 at switch terminal (SW) 103. Switch terminal 103 is coupled to load 190.

Driver 140 includes a supply voltage terminal (VDD) 141, a high side input (HI) terminal 142, a low side input (LI) terminal 143, a signal ground (VSS) terminal 144, a high side floating supply (HB) terminal 145, a high side output (HO) terminal 146, a high side floating supply return (HS) terminal 147, a low side output (LO) terminal 148, and a power ground (COM) terminal 149. Controller 110 includes a first pulse width modulation (PWM1) terminal 111, a second PWM (PWM2) terminal 112, and a signal ground (VSS) terminal 113. The controller's PWM1 terminal 111 is coupled to the driver's HI terminal 142 via resistor RHI. The PWM2 terminal 112 is coupled to the LI terminal 143 via resistor RLI. The VSS terminals 113 and 144 are coupled together.

The drain of transistor M42 is coupled to the HS terminal 147 and the source of transistor M42 is coupled to the COM terminal 149. The gate of transistor M42 is coupled to the LO terminal 148 via resistor RLO. The drain of transistor M41 is coupled to the Vsupply terminal 101. The source of transistor M41 is coupled to the HS terminal 147. The gate of transistor M41 is coupled to the HO terminal 146 via resistor RHO. A bootstrap capacitor CBOOT is coupled between the HB terminal 145 and the HS terminal 147. A bias voltage (Bias) is coupled to the HB terminal 145 by way of resistor RBOOT and diode DBOOT. The voltage across bootstrap capacitor CBOOT causes the voltage on the HB terminal 145 to remain a relatively fixed voltage above the voltage on the HS terminal 147. In one example, the voltage across the bootstrap capacitor CBOOT is 15V. When transistor M42 is on, the voltage on the switch terminal 103 is approximately equal to power ground (terminal 102). When transistor M41 is on, the voltage on the switch terminal 103 is approximately equal to Vsupply. The magnitude of Vsupply can be any suitable voltage. In some examples, Vsupply is 600V or 700V. Accordingly, relative to power ground, the voltage on the source of transistor M41 can range from power ground to relatively high voltage (e.g., 700V).

Driver 140 includes, among other components, gate control circuits 151 and 152. Each gate control circuit has an output. The output of gate control circuit 151 is coupled to the HO terminal 146. The output of gate control circuit 152 is coupled to the LO terminal 148. As described below, gate control circuit 151 causes transistor M41 to turn on and off. Gate control circuit 151 causes transistor M42 to turn on and off.

Driver 140 includes a low side driver to turn on and off transistor M41 and a high side driver to turn on and off transistor M42. Controller 110 generates PWM signals at its PWM1 terminal 111 and PWM2 terminal 112. In an example, responsive to a rising edge or high logic state at the PWM1 terminal 111, which is coupled to the driver's HI terminal 142, the high side driver turns on transistor M41, and responsive to responsive to a falling edge or low logic state at the PWM1 111, the high side driver turns off transistor M41. Similarly, responsive to a rising edge or high logic state at the PWM2 terminal 112, which is coupled to the driver's LI terminal 143, the low side driver turns on transistor M42, and responsive to responsive to a falling edge or low logic state at the PWM2 112, the low side driver turns off transistor M42. Because the source of transistor M42 is coupled to power ground, turning on transistor M42 only requires driver 140 to produce a relatively low voltage (e.g., 3V, 5V, etc.), relative to power ground, at its LO terminal 148. However, because the voltage, relative to power ground, on the source of transistor M41 can vary widely from, for example, power ground to 700V, the high side driver within driver 140 includes a level shift circuit, described below, to produce a sufficient voltage (gate-to-source voltage, Vgs, that is greater than the threshold voltage of transistor M41) to turn on transistor M41. In the example, in which the voltage on the source of transistor M41 ranges from 0V to 700V, the high side driver within driver 140 produces a voltage to the gate of transistor M41, relative to power ground, that varies from 5V to 715V.

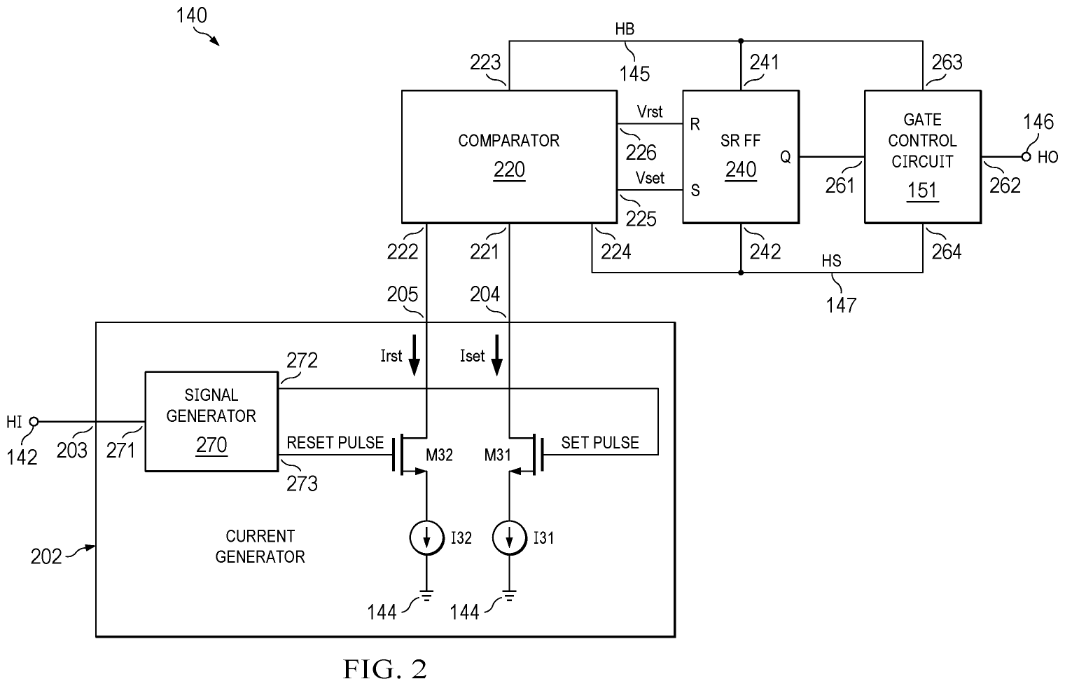

FIG. 2 is a schematic diagram of the high side driver of driver 140, in an example. The example driver 140 of FIG. 2 includes a current generator 202, a comparator 220, a set-reset flip-flop (SR FF) 240, and the gate control circuit 151. In one example, current generator 202 has an input 203 coupled to the HI terminal 142. In other example, other logic may be coupled between the HI terminal 1142 and input 203 of current generator 202. Current generator 202 also includes outputs 204 and 205. Comparator 220 has comparator inputs 221 and 222, comparator outputs 225 and 226 (having voltages Vset and Vrst, respectively), and comparator terminals 223 and 224. Outputs 204 and 205 of current generator 202 are coupled to comparator inputs 221 and 222, respectively. Comparator terminal 222 is coupled to the HB terminal 145, and comparator terminal 224 is coupled to the HS terminal 147.

The SR FF 240 includes a set(S) input, a reset (R) input, and a Q output. Power terminal 241 and ground terminal 242 of the SR FF 240 are coupled to the HB terminal 145 and to the HS terminal 147, respectively. Gate control circuit 151 includes an input 261 coupled to the SR FF's Q output. Gate control circuit 151 also includes an output 262 coupled to the HO terminal 146. Power terminal 263 and ground terminal 264 of gate control circuit 151 are coupled to the HB terminal 145 and to the HS terminal 147, respectively. The power supply voltage to SR FF 240 and to gate control circuit 151 is the HB-HS voltage. Because of the charge on the bootstrap capacitor CBOOT between the HB terminal 145 and the HS terminal 147, the power supply voltage to SR FF 240 and to gate control circuit 151 is the voltage drop across the bootstrap capacitor CBOOT, which in some examples is 15V.

In this example, current generator 202 includes a signal generator 270, transistors M31 and M32, current source circuits I31 and I32 (“I31” and “I32” refer to both the current source circuits and the currents produced therefrom), and capacitors C1 and C2. Signal generator 270 has a signal generator input 271 and signal generator outputs 272 and 273. Signal generator input 271 is coupled to input 203 of current generator 202. Transistors M31 and M32 are NFETs in this example. The gates of transistors M31 and M32 are coupled to signal generator outputs 272 and 273, respectively. Current source circuit I31 is coupled in parallel with capacitor C1 between the source of transistor M31 and signal ground 144. Similarly, current source circuit I32 is coupled in parallel with capacitor C2 between the source of transistor M32 and signal ground 144. The drains of transistors M31 and M32 are coupled to outputs 204 and 205, respectively, of current generator 202. In one example, the current produced by current source circuit I31 is approximately the same as the current produced by current source circuit I32. In an example, current I31 and current I32 are approximately equal to 10 micro-amperes.

Signal generator 270 responds to a rising edge or logic high assertion at signal generator input 271 by outputting a logic signal at output 272 to turn on transistor M31. Similarly, signal generator 270 responds to a falling edge or logic low assertion at signal generator input 271 by outputting a logic signal at output 273 to turn on transistor M32. With transistor M31 on, some of the current flowing through transistor M31 charges capacitor C1 and some of the current is equal to current I31. As capacitor C1 charges, the voltage on the source of transistor increases and, accordingly, the gate-to-source voltage (Vgs) of transistor M31 decreases. Eventually, the Vgs of capacitor M31 becomes small enough to just allow current I31 to flow through transistor M31 and, at that point, charging current for capacitor C1 ceases and current I31 continues to flow through transistor M31 as current Iset. Accordingly, when transistor M31 turns on, initially, current Iset is at a higher level (charging current for capacitor C1 plus current I31) and then when capacitor C1 is charged to a higher voltage level, current Iset reduces to a level equal to current I31. Similarly, when transistor M32 is turned on, current Irst is initially at a higher level as capacitor C2 is charging and then reduces a level equal to current I32.

Comparator 220 compares the current through its comparator input 221 to the current through its comparator input 222. If current Iset is larger than current Irst, then comparator 220 asserts its comparator output 225 to the logic high state. Alternatively, if current Irst is larger than current Iset, then comparator 220 asserts its comparator output 226 to the logic high state.

Responsive to a logic high assertion at the S input of SR FF 240, SR FF 240 forces its Q output to a logic high state, and responsive to a logic low assertion at the S input, SR FF 240 forces its Q output to a logic low state. The logic high and low states are relative to the voltage at the HS terminal 147. Responsive to a logic high assertion at input 261 of gate control circuit 151, the gate control circuit forces its output 262, and thus the HO terminal 146, to a logic high state relative to the voltage at the HS terminal 147 to thereby turn on transistor M41. Responsive to a logic low assertion at input 261 of gate control circuit 151, the gate control circuit forces its output 262 to a logic low state relative to the voltage at the HS terminal 147 to thereby turn off transistor M41.

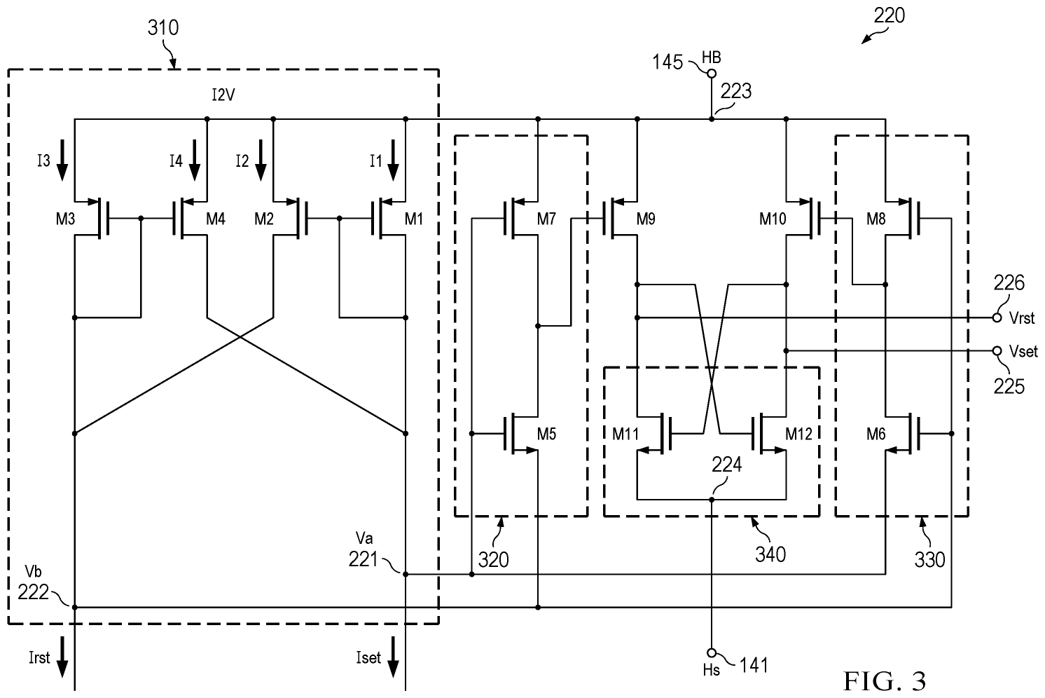

FIG. 3 is a schematic diagram of comparator 220, in an example. Comparator 220 includes a current-to-voltage (12V) converter 310, inverters 320 and 330, a latch 340, and transistors M9 and M10. The I2V converter 310 includes transistors M1. M2, M3, and M4. Transistors M1-M4 are all p-channel field effect transistors (PFETs) in this example but other types of transistors can be used instead. The sources of transistors M1-M4 are coupled together and to the HB terminal 145. The gates of transistors M1 and M2 are coupled together and to the drain of transistor M4 and to comparator input 221. The gates of transistors M3 and M4 are coupled together and to the drain of transistor M3 and to the comparator input 222. The current through transistors M1, M2, M3, and M4 are currents I1, I2, I3, and I4, respectively.

Inverter 320 includes a transistor M7 (e.g., a PFET) coupled to a transistor M5 (e.g., an NFET). The gates of transistors M5 and M7 are coupled together and to comparator input 221. The source of transistor M5 is coupled to comparator input 222. The drains of transistors M5 and M7 are coupled together and to the gate of transistor M9 (e.g., a PFET). The sources of transistors M7 and M9 are coupled together and to comparator terminal 223 and thus to the HB terminal 145. In one example, the size (ratio of channel width to channel length) of transistor M5 is larger than the size of transistor M7. Similarly, transistor M6 is larger than transistor M8. In one example, transistors M5 and M6 are natural mode transistors. A natural mode transistor has a threshold voltage of approximately 0V.

Similarly, inverter 330 includes a transistor M8 (e.g., a PFET) coupled to a transistor M6 (e.g., an NFET). The gates of transistors M6 and M8 are coupled together and to comparator input 222. The source of transistor M6 is coupled to comparator input 221. The drains of transistors M6 and M8 are coupled together and to the gate of transistor M10 (e.g., a PFET). The sources of transistors M9 and M10 are coupled together and to comparator terminal 223 and thus to the HB terminal 145.

In this example, latch 340 includes a pair of cross-coupled transistors M11 and M12 (e.g., NFETs). The sources of transistors M11 and M12 are coupled together and to the comparator 224 and thus to the HS terminal 147. The drain of transistor M11 is coupled to the drain of transistor M9, the gate of transistor M12, and to the comparator output 226. The drain of transistor M12 is coupled to the drain of transistor M10, the gate of transistor M11, and to the comparator output 225. The voltage at comparator output 225 is voltage Vrst, and the voltage at comparator output 226 is voltage Vset.

The I2V converter 310 converts Iset and Irst to voltages Va and Vb at the comparator inputs 221 and 222. The voltage difference between Va and Vb will increase as the difference between currents Iset and Irst increases and will decrease as the difference between currents Iset and Irset decreases. In one example, the relationship between the voltage difference Va-Vb and the current difference Irst-Iset is positive but non-linear.

For example, if Irst is 10 microamperes and Iset is 0 microamperes, current I3 will be approximately 10 microamperes and currents I1, I2, and I4 will be approximately 0 microamperes. The voltage on the gate of transistor M3 will be low enough relative to the voltage of the HB terminal 145 to allow transistor M3 to flow 10 microamperes of current as current I3. The voltage of the gate of transistor M4 (Va) will be approximately equal to the voltage of the HB terminal such that transistor M4 will be off. Accordingly, the voltage Va, relative to the voltage Vb, will be proportional to the current difference Irst-Iset.

Similarly, if Iset is 10 microamperes and Irst is 0 microamperes, current I1 will be approximately 10 microamperes and currents I2-I4 will be approximately 0 microamperes. In this state, Vb will be greater than Va and the voltage difference Vb-Va will be proportional to the current difference Iset-Isrst.

In an example in which current Irst is X and Iset is Y, where X is greater than Y, transistor M3 will flow X current as current I3, and all of the Y current will flow through transistor M4 as current I4. Transistor M1 will not have a sufficiently large Vgs to turn on transistor M2, and thus transistor M1, as well as transistor M2, will be off in this example. The voltage on the gate of transistor M3 (Vb) will be at a level that transistor M3 will flow a current I3 equal to current Irst, and the voltage on the drain of transistor M4 (Va) will be at a level that transistor M4 will flow a current I4 equal to current Iset. Accordingly, the voltage difference Va-Vb will be related to the current difference Irst-Iset as described above.

Similarly, if Iset is greater than Irst, current I1 will be equal to Iset and current I2 will be equal to current Irst. In this state, the voltage difference Vb-Va will be proportional to the current difference Iset-Irst.

The voltage Va is applied to the gate of transistor M5, and the voltage Vb is applied to the source of transistor M5. By contrast, the voltage Vb is applied to the gate of transistor M6, and the voltage Va is applied to the source of transistor M6. In this configuration, only one of transistors M5 and M6 will be on at any point in time.

If Va is larger than Vb, transistors M5 and M8 will be on and transistors M6 and M7 will be off. Transistor M5 being on causes transistor M9 to turn on, which also pulls the gate voltage of transistor M12 high enough to turn on transistor M12. With transistor M12 on, the voltage on the gate of transistor M11 is pulled low to the voltage at the HS terminal 147 which causes transistor M11 to be off. Transistor M8 being on causes transistor M10 to be off. With transistors M9 and M12 on and transistors M10 and M11 off, the voltage Vrst at the comparator output 226 will be forced upward to approximately the voltage at the HB terminal 145, and the voltage Vset at the comparator output 225 will be forced low to approximately the voltage of the HS terminal 147.

Similarly, if Vb is larger than Va, transistors M6 and M7 will be on and transistors M5 and M8 will be off. Transistor M6 being on causes transistor M10 to turn on, which also pulls the gate voltage of transistor M11 high enough to turn on transistor M11. With transistor M11 on, the voltage on the gate of transistor M12 is pulled low to the voltage at the HS terminal 147 which causes transistor M12 to be off. Transistor M7 being on causes transistor M9 to be off. With transistors M10 and M11 on and transistors M9 and M12 off, the voltage Vset at the comparator output 225 will be forced upward to approximately the voltage at the HB terminal 145, and the voltage Vrst at the comparator output 226 will be forced low to approximately the voltage of the HS terminal 147.

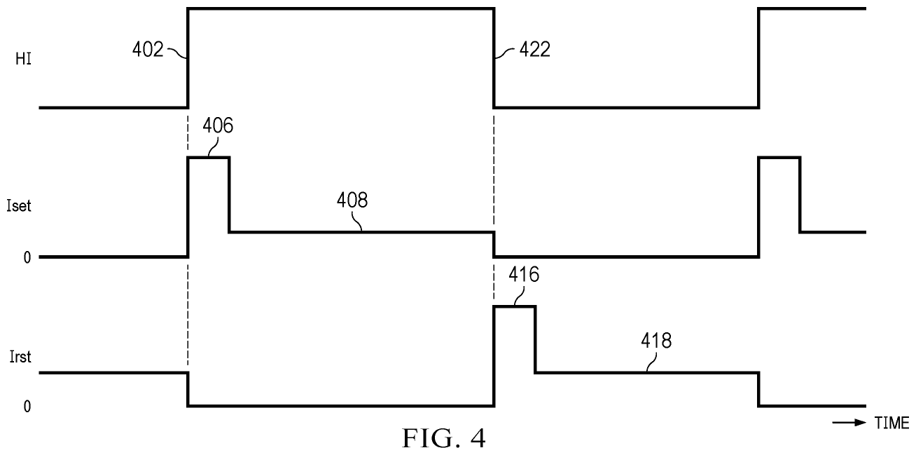

FIG. 4 is a timing diagram illustrating an example of the operation of current generator 202. The signals shown in FIG. 4 include the signal at the HI input terminal 142, the Iset current, and the Irst current. At a rising edge 402 of the signal at the HI input terminal 142, the signal generator 270 turns on transistor M31 which causes Iset to pulse high at 406 as capacitor C1 begins to charge. Then, when the voltage across capacitor C1 reaches a level for which the Vgs of transistor M31 is low enough to only allow current I31 through the transistor, current Iset reduces to level 408 which is the magnitude of current I31. Both the current levels at 406 and 408 are greater than 0 amperes. Because transistor M32 is off, current Irst is at 0 amperes during this period of time. Then, the signal generator 270 responds to a falling edge 422 of the signal at the HI input terminal 142 by turning off transistor M31 and turning on transistor M32, which causes current Irst to pulse high at 416 as capacitor C2 begins to charge. Then, when the voltage across capacitor C2 reaches a level for which the Vgs of transistor M32 is low enough to only allow current I32 through the transistor, current Irst reduces to level 418 which is the magnitude of current I32. Both levels of current 416 and 418 are greater than 0 amperes. Because transistor M31 is off, current Iset is at 0 amperes during this period of time.

In any case, one of currents Irst and Iset is greater than 0 amperes at any point in time. This continuous current condition implemented by current generator 202 avoids the problem described above in which a current pulse could be missed by a comparator. Instead, in the example of FIGS. 1-3, one or the other comparator input 221 and 222 has a non-zero current flowing at any point in time, and comparator 220 is able to detect relatively low current differences between Iset and Irst at inputs 221 and 222 to enable gate control of the high side transistor based on those current differences.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A driver, comprising:
a current generator having an input, a first output, and a second output, the current generator configured to generate a first current at the first output while a signal at the input is at a first logic state and to generate a second current at the second output while the signal at the input is at a second logic state;
a comparator having a first comparator input, a second comparator input, and a first comparator output, and a second comparator output, the first comparator input coupled to the first output, the second comparator input coupled to the second output;
a latch having a first latch input, a second latch input, and a latch output, the first latch input coupled to the first comparator output, and the second latch input coupled to the second comparator output; and
a gate control circuit having an input coupled to the latch output.

2. The driver of claim 1, wherein the comparator is configured to:
generate a first output signal at a first logic state at the first comparator output responsive to the first current being greater than the second current; and
generate a second output signal at the first logic state at the second comparator output responsive to the second current being greater than the first current.

3. The driver of claim 1, wherein the latch is a set-reset latch.

4. The driver of claim 1, wherein the comparator comprises:
a current-to-voltage (12V) converter having a first I2V input, a second I2V input, a first I2V output, and a second I2V output, the first I2V input coupled to the first comparator input, and the second I2V input coupled to the second comparator input;
a first inverter having an input coupled to the first 12V output; and
a second inverter having an input coupled to the second I2V output.

5. The driver of claim 4, wherein the first inverter has a first inverter output, the second inverter has a second inverter output, and the driver further comprises:
a first pair of transistors coupled between a first terminal and a second terminal, the first pair of transistors having an input coupled to the first inverter output;
a second pair of transistors coupled between the first terminal and the second terminal, the second pair of transistors cross-coupled to the first pair of transistors and having an input coupled to the second inverter output.

6. The driver of claim 4, wherein the I2V converter comprises:
a first transistor having a control input and first and second terminals, the second terminal coupled to the first comparator input;
a second transistor having a control input and first and second terminals, the control inputs of the first and second transistors coupled together;
a third transistor having a control input and first and second terminals, the second terminal of the third transistor coupled to the second comparator input and to the second terminal of the second transistor; and
a fourth transistor having a control input and first and second terminals, the control inputs of the third and fourth transistors coupled together, the second terminals of the first and fourth transistors coupled together.

7. The driver of claim 1, wherein the current generator comprises:
a first transistor having a control input and first and second terminals, the first terminal of the first transistor coupled to the first output;
a second transistor having a control input and first and second terminals, the first terminal of the second transistor coupled to the second output;
a first current source circuit coupled to the second terminal of the first transistor;
a second current source circuit coupled to the second terminal of the second transistor;
a signal generator having:
an input coupled to the input of the current generator;
a first output coupled to the control input of the first transistor; and
a second output coupled to the control input of the second transistor.

8. The driver of claim 7, wherein the signal generator is configured to:
to turn on the first transistor in response to the signal at the input of the signal generator being at the first logic state; and
to turn on the second transistor in response to the signal at the input of the signal generator being at the second logic state.

9. An apparatus, comprising:
a controller having a controller output;
a current generator having an input, a first output, and a second output, the input of the current generator coupled to the controller output, the current generator configured to generate a first current at the first output while a signal at the input is at a first logic state and to generate a second current at the second output while the signal at the input is at a second logic state;
a comparator having a first comparator input, a second comparator input, and a first comparator output, and a second comparator output, the first comparator input coupled to the first output, the second comparator input coupled to the second output;
a latch having a first latch input, a second latch input, and a latch output, the first latch input coupled to the first comparator output, and the second latch input coupled to the second comparator output;
a gate control circuit having an unput and an output, the input of the gate control circuit coupled to the latch output; and
a transistor having a control input coupled to the output of the gate control circuit.

10. The apparatus of claim 9, wherein the transistor is a first transistor having first and second terminals, and the gate control circuit is a first gate control circuit, and the apparatus further comprises:
a second gate control circuit having an output; and
a second transistor having a control input and first and second terminals, the first terminal of the second transistor coupled to the second terminal of the first transistor, and the control input of the second transistor coupled to the output of the second gate control circuit.

11. The apparatus of claim 9, wherein the comparator is configured to:
generate a first output signal at a first logic state at the first comparator output responsive to the first current being greater than the second current; and
generate a second output signal at the first logic state at the second comparator output responsive to the second current being greater than the first current.

12. The apparatus of claim 9, wherein the comparator comprises:
a current-to-voltage (12V) converter having a first I2V input, a second I2V input, a first I2V output, and a second I2V output, the first I2V input coupled to the first comparator input, and the second I2V input coupled to the second comparator input;
a first inverter having an input coupled to the first I2V output; and
a second inverter having an input coupled to the second I2V output.

13. The apparatus of claim 12, wherein the first inverter has a first inverter output, the second inverter has a second inverter output, and the apparatus further comprises:
a first pair of transistors coupled between a first terminal and a second terminal, the first pair of transistors having an input coupled to the first inverter output;
a second pair of transistors coupled between the first terminal and the second terminal, the second pair of transistors cross-coupled to the first pair of transistors and having an input coupled to the second inverter output.

14. The apparatus of claim 12, wherein the I2V converter comprises:
a first transistor having a control input and first and second terminals, the second terminal coupled to the first comparator input;
a second transistor having a control input and first and second terminals, the control inputs of the first and second transistors coupled together;
a third transistor having a control input and first and second terminals, the second terminal of the third transistor coupled to the second comparator input and to the second terminal of the second transistor; and
a fourth transistor having a control input and first and second terminals, the control inputs of the third and fourth transistors coupled together, the second terminals of the first and fourth transistors coupled together.

15. A circuit, comprising:
a current-to-voltage (12V) converter having a first I2V input, a second I2V input, a first I2V output, and a second I2V output;
a first inverter having an input coupled to the first I2V output; and
a second inverter having an input coupled to the second I2V output.

16. The circuit of claim 15, wherein the first inverter has a first inverter output, the second inverter has a second inverter output, and the circuit further comprises:
a first pair of transistors coupled between a first terminal and a second terminal, the first pair of transistors having an input coupled to the first inverter output;
a second pair of transistors coupled between the first terminal and the second terminal, the second pair of transistors cross-coupled to the first pair of transistors and having an input coupled to the second inverter output.

17. The circuit of claim 16, wherein:
the first pair of transistors includes a first transistor coupled in series with a second transistor, the first transistor having a control input coupled to the first inverter output; and
the second pair of transistors includes a third transistor coupled in series with a fourth transistor, the third transistor having a control input coupled to the second inverter output.

18. The circuit of claim 15, wherein the I2V converter comprises:
a first transistor having a control input and first and second terminals;
a second transistor having a control input and first and second terminals, the control inputs of the first and second transistors coupled together;
a third transistor having a control input and first and second terminals, the second terminal of the third transistor coupled to the second terminal of the second transistor; and
a fourth transistor having a control input and first and second terminals, the control inputs of the third and fourth transistors coupled together, the second terminals of the first and fourth transistors coupled together.

19. The circuit of claim 18, further comprising:
a first current source circuit;
a second current source circuit;
a fifth transistor coupled between the second terminal of the first transistor and the first current source circuit; and
a sixth transistor coupled between the second terminal of the third transistor and the second current source circuit.

20. The circuit of claim 15, wherein the 12V converter is configured to convert a differential current at the first and second I2V inputs to a differential voltage at the first and second I2V outputs.
